(19) United States
(12) Patent Application Publication
(10) Pub. No.: US 2024/0422994 A1
(43) Pub. Date: Dec. 19, 2024

(54) SEMICONDUCTOR MEMORY DEVICE

(71) Applicant: SAMSUNG ELECTRONICS CO., LTD., SUWON-SI (KR)

(72) Inventors: Youngsun Song, Suwon-si (KR); Seulji Song, Suwon-si (KR)

(21) Appl. No.: 18/653,689

(22) Filed: May 2, 2024

(30) Foreign Application Priority Data
Jun. 19, 2023 (KR) 10-2023-0078205

(51) Int. Cl. H10B 63/00

(52) U.S. Cl. CPC H10B 63/845; H10B 63/34

(57) ABSTRACT

A semiconductor memory device includes a first source line extending in a first horizontal direction, a second source line extending on the first source line in the first horizontal direction, a plurality of word line plates arranged apart from each other in a vertical direction, between the first source line and the second source line, a vertical bit line configured to penetrate the plurality of word line plates and extending in the vertical direction, a selector arranged between the plurality of word line plates and the vertical bit line, a first vertical channel transistor arranged between the vertical bit line and the first source line, and a second vertical channel transistor arranged between the vertical bit line and the second source line.

### CROSS-REFERENCE TO RELATED APPLICATION

This application is based on and claims priority under 35 U.S.C. § 119 to Korean Patent Application No. 10-2023-0078205, filed on Jun. 19, 2023 in the Korean Intellectual Property office, the disclosure of which is incorporated by reference herein in its entirety.

### BACKGROUND

The inventive concept relates to a semiconductor memory device, and more particularly, to a three-dimensional (3D) semiconductor memory device.

As electronic products become increasingly miniaturized, multi-functional, and higher performance, interest in high-capacity semiconductor memory devices increases. To provide such high-capacity semiconductor memory devices, an increased degree of integration is utilized. Because the degree of integration of conventional two-dimensional (2D) semiconductor memory devices is mainly determined by the area occupied by unit memory cells, the degree of integration of the 2D semiconductor memory devices increases but is still limited. To address this issue, 3D semiconductor memory devices having an increased memory capacity by stacking a plurality of memory cells on substrates in a vertical direction have been proposed.

### SUMMARY

The inventive concept provides a three-dimensional (3D) semiconductor memory device with an improved degree of integration and improved operational reliability.

The inventive concept provides semiconductor memory devices as follows.

According to an aspect of the inventive concept, there is provided a semiconductor memory device including a first source line extending in a first horizontal direction; a second source line extending in the first horizontal direction; a plurality of word line plates arranged apart from each other in a vertical direction, between the first source line and the second source line; a vertical bit line extending through the plurality of word line plates in the vertical direction; a selector arranged between the plurality of word line plates and the vertical bit line; a first vertical channel transistor between the vertical bit line and the first source line; and a second vertical channel transistor between the vertical bit line and the second source line.

According to another aspect of the inventive concept, there is provided a semiconductor memory device including at least one first source line extending in a first horizontal direction; at least one second source line extending in the first horizontal direction parallel with the at least one first source line; a plurality of word line plates arranged apart from each other in a vertical direction and extending in each of the first horizontal direction and a second horizontal direction orthogonal to the first horizontal direction, between the at least one first source line and the at least one second source line; a plurality of vertical bit lines, extending in the vertical direction, and each extending through the plurality of word line plates, and being spaced apart from each other in each of the first horizontal direction and the second horizontal direction; a plurality of selectors respectively separating the plurality of word line plates from the plurality of vertical bit lines; a plurality of first vertical channel transistors respectively arranged between the plurality of vertical bit lines and the at least one first source line; and a plurality of second vertical channel transistors respectively arranged between the plurality of vertical bit lines and the at least one second source line, wherein the plurality of word line plates, one vertical bit line among the plurality of vertical bit lines, and the selectors separating the plurality of word line plates and the one vertical bit line among the plurality of selectors constitute a memory cell string including a plurality of memory cells.

According to another aspect of the inventive concept, there is provided a semiconductor memory device including a plurality of first source lines extending in parallel with each other in a first horizontal direction; a plurality of second source lines extending in parallel with each other in the first horizontal direction; a plurality of word line plates spaced apart from each other in a vertical direction and extending in each of the first horizontal direction and a second horizontal direction orthogonal to the first horizontal direction, between the plurality of first source lines and the plurality of second source lines; a plurality of vertical bit lines respectively, extending in the vertical direction, and extending through the plurality of word line plates, and being spaced apart from each other in each of the first horizontal direction and the second horizontal direction; a plurality of selectors respectively arranged between the plurality of vertical bit lines and the plurality of word line plates, the plurality of selectors each including a selection substance layer having ovonic threshold switching (OTS) characteristics, a first selection electrode layer arranged between the selection substance layer and each of the plurality of vertical bit lines, and a second selection electrode layer arranged between each of the plurality of word line plates and the selection substance layer; a plurality of first semiconductor structures each including a first source region, a first channel region, and a first drain region, the plurality of first semiconductor structures being sequentially arranged from the plurality of first source lines toward the plurality of vertical bit lines; a plurality of first gate lines extending in parallel with each other in the second horizontal direction, and surrounding the first channel regions of the plurality of first semiconductor structures; a plurality of first gate insulating layers arranged between the plurality of first gate lines and the first channel regions of the plurality of first semiconductor structures; a plurality of second semiconductor structures each including a second source region, a second channel region, and a second drain region, the plurality of second semiconductor structures being sequentially arranged from the plurality of second source lines toward the plurality of vertical bit lines; a plurality of second gate lines extending in parallel with each other in the second horizontal direction, and surrounding the second channel regions of the plurality of second semiconductor structures; and a plurality of second gate insulating layers arranged between the plurality of second gate lines and the second channel regions of the plurality of second semiconductor structures.

### BRIEF DESCRIPTION OF THE DRAWINGS

Embodiments will be more clearly understood from the following detailed description taken in conjunction with the accompanying drawings in which:

FIG. 1 is a perspective view of a semiconductor memory device, according to an embodiment;

FIGS. 2A and 2B are vertical cross-section views of a semiconductor memory device, according to embodiments;

FIGS. 3A through 3C are diagrams of a memory cell and a memory cell string, according to embodiments;

FIG. 4 is an equivalent circuit diagram of a semiconductor memory device according to an embodiment;

FIGS. 5A and 5B are diagrams for describing operations of a semiconductor memory device, according to embodiments;

FIGS. 6A and 6B are perspective views of semiconductor memory devices, according to embodiments;

FIG. 7 is a perspective view of a semiconductor memory device according to an embodiment, and FIGS. 8A and 8B are vertical cross-section views of a semiconductor memory device according to embodiments;

FIGS. 9A and 9B are diagrams for describing operations of a semiconductor memory device, according to embodiments;

FIG. 10 is a diagram for describing characteristics of a semiconductor memory device according to an embodiment;

FIG. 11 is a perspective view of a semiconductor memory device according to an embodiment;

FIGS. 12A and 12B are vertical cross-section views of a semiconductor memory device, according to embodiments; and

FIG. 13 is an equivalent circuit diagram for describing an operation of a semiconductor memory device, according to an embodiment.

### DETAILED DESCRIPTION OF THE EMBODIMENTS

Principles and Embodiments of the Present Invention Relate to

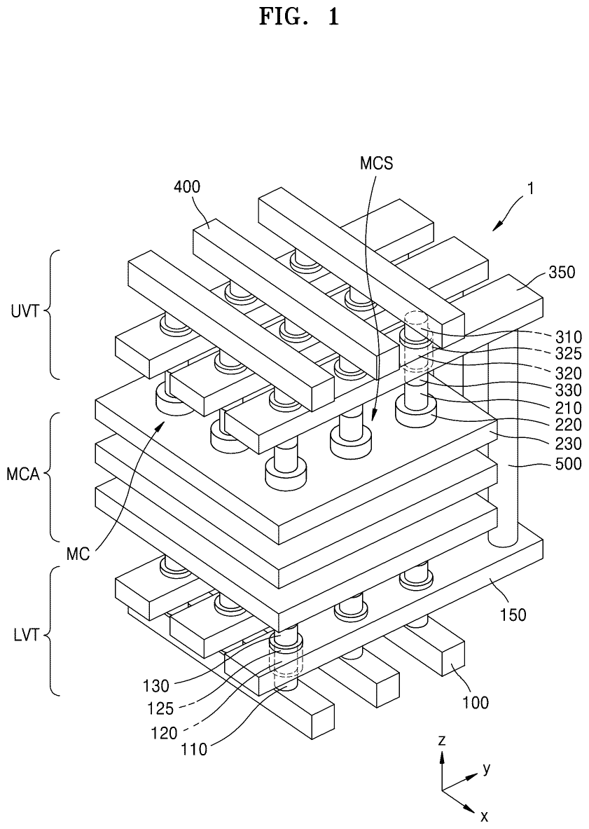

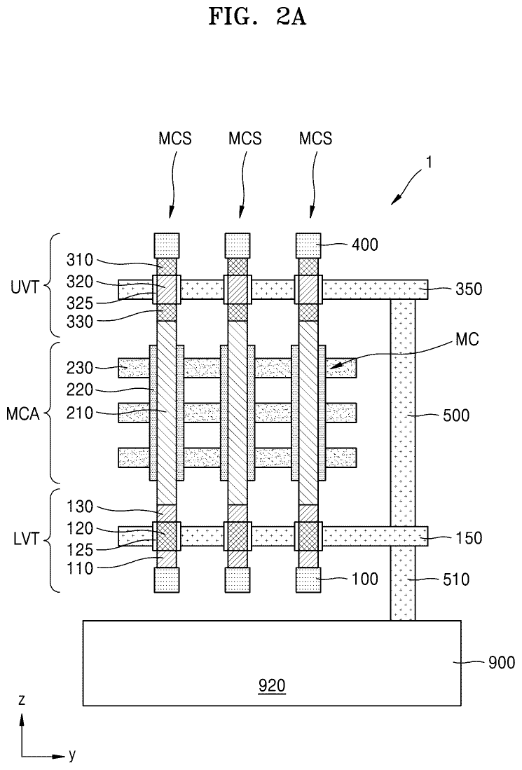

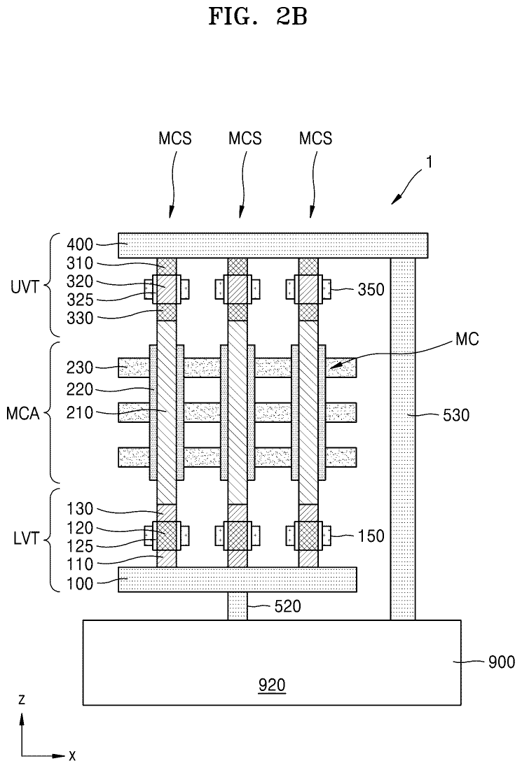

FIG. 1 is a perspective view of a semiconductor memory device 1 according to an embodiment, and FIGS. 2A and 2B are vertical cross-section views of the semiconductor memory device 1, according to embodiments.

Referring to FIGS. 1, 2A, and 2B, the semiconductor memory device 1 may include a plurality of first source lines 100, a plurality of second source lines 400, a plurality of memory cell strings MCS arranged between the plurality of first source lines 100 and the plurality of second source lines 400, a plurality of first vertical channel transistors LVT arranged between the plurality of first source lines 100 and the plurality of second source lines 400, and a plurality of second vertical channel transistors UVT arranged between the plurality of second source lines 400 and the plurality of memory cell strings MCS.

In various embodiments, the plurality of first source lines 100 may extend in a first horizontal direction (X direction), where for example, the plurality of first source lines 100 may extend in parallel with each other in the first horizontal direction (X direction). The plurality of first source lines 100 may be arranged apart from each other in a second horizontal direction (Y direction) different from the first horizontal direction (X direction). In various embodiments, the plurality of first source lines 100 may be arranged apart from each other at an equal interval in the second horizontal direction (Y direction). In various embodiments, the first horizontal direction (X direction) and the second horizontal direction (Y direction) may be orthogonal to each other.

The plurality of second source lines 400 may be arranged above the plurality of first source lines 100, where for example, the plurality of second source lines 400 may be spaced apart from the plurality of first source lines 100 in a vertical direction (Z direction). The vertical direction (Z direction) may be perpendicular to each of the first horizontal direction (X direction) and the second horizontal direction (Y direction). The plurality of second source lines 400 may extend in the first horizontal direction (X direction), where for example, the plurality of second source lines 400 may extend in parallel with each other in the first horizontal direction (X direction). The plurality of second source lines 400 may be arranged apart from each other in the first horizontal direction (X direction). In various embodiments, the plurality of second source lines 400 may be arranged apart from each other at an equal interval in the first horizontal direction (X direction).

In various embodiments, the plurality of first source lines 100 and the plurality of second source lines 400 may be arranged to be aligned with each other in the vertical direction (Z direction), where a second source line 400 overlying a first source line 100 in the vertical direction (Z direction) may be aligned with each other along a vertical (x-z) plane. The first source line 100 may be referred to as a lower source line, and the second source line 400 may be referred to as an upper source line.

In various embodiments, the plurality of memory cell strings MCS may include a plurality of vertical bit lines 210, a plurality of word line plates 230, and a plurality of selectors 220 arranged between the plurality of vertical bit lines 210 and the plurality of word line plates 230. The vertical bit line 210 and the word line plate 230 associated with each other, and the selector 220 arranged between the vertical bit line 210 and the word line plate 230 associated with each other may constitute a memory cell MC. The semiconductor memory device 1 may include a 3D semiconductor memory device including a selector-only memory (SOM) or a self-selecting memory. The selectors 220 arranged between one vertical bit line 210 and the plurality of word line plates 230 may constitute one memory cell string MCS. The memory cell string MCS may include a plurality of memory cells MC. The plurality of memory cell strings MCS may constitute a memory cell array MCA. The memory cell array MCA may be arranged between the plurality of first vertical channel transistors LVT and the plurality of second vertical channel transistors UVT. The first vertical channel transistor LVT may be referred to as a lower vertical channel transistor, and the second vertical channel transistor UVT may be referred to as an upper vertical channel transistor.

In various embodiments, the plurality of vertical bit lines 210 may be spaced apart from each other in a horizontal direction, for example, in each of the first horizontal direction (X direction) and the second horizontal direction (Y direction), where each of the plurality of vertical bit lines 210 may extend in the vertical direction (Z direction). The plurality of vertical bit lines 210 may be arranged in a matrix (array) form in a plan view but are not limited thereto. For example, the plurality of vertical bit lines 210 may also be arranged in a hexagonal form in a plan view. The vertical bit line 210 may be referred to as a vertical filler. Each of the plurality of vertical bit lines 210 may have, for example, a cylindrical shape, but is not limited thereto. For example, each of the plurality of vertical bit lines 210 may also have a rectangular pillar shape. Each of the plurality of vertical bit lines 210 may include a conductive material. For example, each of the plurality of vertical bit lines 210 may include doped polysilicon, a metal, a conductive metal nitride, or a combination thereof.

In various embodiments, each of the plurality of word line plates 230 may have a flat plate shape extending in each of the first horizontal direction (X direction) and the second horizontal direction (Y direction) with a thickness therebetween (e.g., rectangular prism). The plurality of word line plates 230 may be arranged apart from each other in the vertical direction (Z direction).

In various embodiments, the plurality of selectors 220 may surround at least a portion of each of the plurality of vertical bit lines 210, where a single selector 220 may be around a single vertical bit line 210. In a plan view, the selector 220 may have a ring shape surrounding the vertical bit line 210 corresponding thereto. In various embodiments, the selector 220 may have a circular ring shape (e.g., annular cylinder) in a plan view but is not limited thereto, and the shape of the selector 220 in a plan view may be determined according to the shape of the vertical bit line 210. For example, when the vertical bit line 210 has a rectangular pillar shape, in a plan view, the shape of the selector 220 may have a rectangular ring shape. In some embodiments, an uppermost end of each of the plurality of selectors 220 may be at a greater vertical level than an upper surface of the word line plate 230 at the uppermost end among the plurality of word line plates 230, but is not limited thereto. For example, the uppermost end of each of the plurality of selectors 220 may be at the same vertical level as the upper surface of the word line plate 230 at the uppermost end among the plurality of word line plates 230. In various embodiments, a lowermost end of each of the plurality of selectors 220 may be at a lower vertical level than a lower surface of the word line plate 230 at a lowermost end among the plurality of word line plates 230, but is not limited thereto. For example, the lowermost end of each of the plurality of selectors 220 may be at the same vertical level as the lower surface of the word line plate 230 at the lowermost end among the plurality of word line plates 230.

In FIGS. 2A and 2B, it is illustrated that the selector 220 included in the memory cell string MCS extends from above the upper surface of the word line plate 230 at the uppermost end among the plurality of word line plates 230 to below the lower surface of the word line plate 230 at the lowermost end of the plurality of word line plates 230, where the selector 220 may extend through a plurality of word line plate 230, but the embodiment is not limited thereto. For example, the memory cell string MCS may include the selectors 220 surrounding each of the portions surrounded by the plurality of word line plates 230 among the vertical bit lines 210 and being apart from each other, where the vertical bit lines 210 may extend through a plurality of word line plate 230. For example, one memory cell string MCS may include one vertical bit line 210, and one selector 220 forming one body and extending coaxially with the one vertical bit line 210 and between the one vertical bit line 210 and the plurality of word line plates 230. Alternatively, for example, one memory cell string MCS may include one vertical bit line 210, and the selectors 220 each arranged between the one vertical bit line 210 and the plurality of word line plates 230 and apart from each other in the vertical direction (Z direction).

In various embodiments, the plurality of first vertical channel transistors LVT may include a plurality of first source regions 110, a plurality of first channel regions 120, a plurality of first drain regions 130, a plurality of first gate lines 150, and a plurality of first gate insulating layers 125 arranged between the plurality of first channel regions 120 and the plurality of first gate lines 150. The first source region 110 may be referred to as a lower source region, the first channel region 120 may be referred to as a lower channel region, the first gate insulating layer 125 may be referred to as a lower gate insulating layer, the first drain region 130 may be referred to as a lower drain region, and the first gate line 150 may be referred to as a lower gate line.

In various embodiments, the first source region 110, the first channel region 120, the first drain region 130, the first gate line 150, and the first gate insulating layer 125 associated with each other may constitute the first vertical channel transistor LVT. The first source region 110, the first channel region 120, and the first drain region 130 associated with each other may be sequentially arranged in the vertical direction (Z direction). The first source regions 110, adjoining first channel regions 120, adjoining first drain regions 130 may be collinear with each other and with a corresponding vertical bit line 210. The first source region 110, the first channel region 120, and the first drain region 130 associated with each other may be referred to as a first semiconductor structure.

In various embodiments, the first source region 110, the first channel region 120, and the first drain region 130 associated with each other may be sequentially arranged in the vertical direction (Z direction) from the first source line 100 toward the second source line 400. In some embodiments, the first source region 110, the first channel region 120, and the first drain region 130 associated with each other may have substantially the same horizontal width and horizontal area. For example, the first source region 110, the first channel region 120, the first drain region 130 associated with each other may have the same horizontal width in each of the first horizontal direction (X direction) and the second horizontal direction (Y direction). In some embodiments, each of the first source region 110 and the first drain region 130 may include a first conductivity type, and the first channel region 120 may have a second conductivity type different from the first conductivity type.

In various embodiments, the plurality of first channel regions 120 and the plurality of first gate lines 150 may be substantially at the same vertical level, the plurality of first gate insulating layers 125 and each of the plurality of first channel regions 120 and the plurality of first gate lines 150 may be substantially at the same vertical level, and the plurality of first source regions 110 may be at a vertical level between the plurality of first gate lines 150 and the plurality of first source lines 100. The first gate insulating layers 125 and the first channel regions 120 may extend above and/or below the first gate lines 150. For example, the plurality of first source regions 110 may be at a lower vertical level than the plurality of first gate lines 150, where the first source regions 110 may be proximal to the first source lines 100. The plurality of first drain regions 130 may be at a vertical level between the plurality of first gate lines 150 and the memory cell array MCA. For example, the plurality of first drain regions 130 may be at a higher vertical level than the plurality of first gate lines 150, where the first drain regions 130 may be distal from the first source lines 100.

In various embodiments, the plurality of first gate lines 150 may extend in the second horizontal direction (Y direction), and surround the plurality of first channel regions 120. For example, the plurality of first gate lines 150 may extend in parallel with each other in the second horizontal direction (Y direction). The plurality of first gate lines 150 may be arranged apart from each other in the first horizontal direction (X direction). In some embodiments, the plurality of first gate lines 150 may be arranged apart from each other at an equal interval in the first horizontal direction (X direction). For example, the plurality of first gate lines 150 and the plurality of first source lines 100 may cross each other and extend in a plan view.

In various embodiments, the plurality of second vertical channel transistors UVT may include a plurality of second source regions 310, a plurality of second channel regions 320, a plurality of second drain regions 330, a plurality of second gate lines 350, and a plurality of second gate insulating layers 325 arranged between the plurality of second channel regions 320 and the plurality of second gate lines 350. The second source region 310 may be referred to as an upper source region, the second channel region 320 may be referred to as an upper channel region, the second gate insulating layer 325 may be referred to as an upper gate insulating layer, the second drain region 330 may be referred to as an upper drain region, and the second gate line 350 may be referred to as an upper gate line.

In various embodiments, the second source region 310, the second channel region 320, the second drain region 330, the second gate line 350, and the second gate insulating layer 325 may constitute the second vertical channel transistor UVT. The second drain region 330, the second channel region 320, and the second source region 310 associated with each other may be sequentially arranged in the vertical direction (Z direction). The second source regions 310, adjoining second channel regions 320, adjoining second drain region 330 may be collinear with each other and with a corresponding vertical bit line 210. The second drain region 330, the second channel region 320, and the second source region 310 associated with each other may be referred to as a second semiconductor structure.

In various embodiments, the second drain region 330, the second channel region 320, and the second source region 310 associated with each other may be sequentially arranged in the vertical direction (Z direction), from the first source line 100 toward the second source line 400, where the second source region 310 may be proximal to the second source line 400. In other words, the second source region 310, the second channel region 320, and the second drain region 330 may be sequentially arranged, from the second source line 400 toward the first source line 100. In some embodiments, the second source region 310, the second channel region 320, and second drain region 330 associated with each other may have substantially the same horizontal width and horizontal area. For example, the second source region 310, the second channel region 320, and the second drain region 330 associated with each other may have the same horizontal width in each of the first horizontal direction (X direction) and the second horizontal direction (Y direction). Invarious embodiments, each of the second source region 310 and the second drain region 330 may include a second conductivity type, and the second channel region 320 may have a first conductivity type.

Each of the first semiconductor structure and the second semiconductor structure may include a semiconductor material. In various embodiments, each of the first semiconductor structure and the second semiconductor structure may include monocrystalline Si, or polysilicon. In various embodiment, each of the first semiconductor structure and the second semiconductor structure may include a two-dimensional (2D) semiconductor material or an oxide semiconductor material. For example, the 2D semiconductor material may include molybdenum sulfide (MoS₂), tungsten diselenide (WSe₂), graphene, carbon nano tube, or a combination thereof. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, each of the first semiconductor structure and the second semiconductor structure may include a single layer or a multilayer of the oxide semiconductor material. In some embodiments, each of the first semiconductor structure and the second semiconductor structure may include a material having a bandgap greater than the bandgap of Si. For example, each of the first semiconductor structure and the second semiconductor structure may include a material having a bandgap of about 1.5 eV to about 5.6 eV.

Each of the first semiconductor structure and the second semiconductor structure may include at least one of a high-k dielectric material having a higher dielectric constant than silicon oxide and ferroelectric material. In various embodiments, each of the first semiconductor structure and the second semiconductor structure may have a stacked structure of a first dielectric layer including silicon oxide and a second dielectric layer including at least one of a high dielectric material and a ferroelectric material. For example, a high dielectric material and a ferroelectric material may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), or lead scandium tantalum oxide (PbScTaO).

Each of the first source line 100, the second source line 400, the first gate line 150, the second gate line 350, and the word line plate(s) 230 may include doped silicon, a metal, a conductive metal nitride, a conductive metal silicide, or a combination thereof. In some embodiments, each of the first gate line 150, the second gate line 350, and the word line plate(s) 230 may include a conductive barrier layer and a conductive filling layer covering the conductive barrier layer. The conductive barrier layer may include, for example, a metal, a conductive metal nitride, a conductive metal silicide, or a combination thereof. For example, the conductive barrier layer may include TiN. The conductive filling layer may include, for example, doped silicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof. In some embodiments, the conductive filling layer may include W.

In various embodiments, the first vertical channel transistor LVT may include a p-type metal-oxide semiconductor field effect transistor (MOSFET), and the second vertical channel transistor UVT may include an n-type MOSFET. For example, the first conductivity type may include a p-type and the second conductivity type may be an n-type. In some other embodiments, the first vertical channel transistor LVT may include an n-type MOSFET, and the second vertical channel transistor UVT may include a p-type MOSFET. For example, the first conductivity type may be n-type and the second conductivity type may be p-type. The first vertical channel transistor LVT may include a MOSFET of a different type from that of the second vertical channel transistor UVT.

In various embodiments, the plurality of second channel region 320 and the second gate line 350 may be substantially at the same vertical level, the plurality of second gate insulating layers 325 and each of the plurality of second channel regions 320 and the plurality of second gate lines 350 may be substantially at the same vertical level, and the plurality of second source regions 310 may be at a vertical level between the plurality of second gate lines 350 and the plurality of second source lines 400. The second gate insulating layers 325 and the second channel regions 320 may extend above and/or below the second gate lines 350. For example, the plurality of second source regions 310 may be at a higher vertical level than the plurality of second gate lines 350. The plurality of second drain regions 330 may be arranged at a vertical level between the plurality of second gate lines 350 and the memory cell array MCA. For example, the plurality of second drain regions 330 may be arranged at a lower vertical level than the plurality of second gate lines 350.

In various embodiments, the plurality of second gate lines 350 may extend in the second horizontal direction (Y direction), and surround the plurality of second channel regions 320. For example, the plurality of second gate lines 350 may extend in parallel with each other in the second horizontal direction (Y direction). The plurality of second gate lines 350 may be arranged apart from each other in the first horizontal direction (X direction). In various embodiments, the plurality of second gate lines 350 may be arranged apart from each other at an equal interval in the first horizontal direction (X direction). The plurality of second gate lines 350 and the plurality of second source lines 400 may cross each other and extend in a plan view.

In various embodiments, the plurality of first gate lines 150 and the plurality of second gate lines 350 may be arranged to be aligned with each other in the vertical direction (Z direction), where the first gate line 150 and the second gate line 350 associated with each other among the plurality of first gate lines 150 and the plurality of second gate lines 350 may be aligned with each other in the vertical direction (Z direction), respectively.

In various embodiments, a plurality of first contact vias 500 may be arranged between the plurality of first gate lines 150 and the plurality of second gate lines 350. The plurality of first contact vias 500 may extend in the vertical direction (Z direction). The first gate line 150 and the second gate line 350 associated with each other among the plurality of first gate lines 150 and the plurality of second gate lines 350 may be electrically connected to each other via at least one first contact via 500 among the plurality of first contact vias 500. The first gate line 150 and the second gate line 350 associated with each other may be electrically connected to each other via the first contact via 500 to be equipotential.

In various embodiments, the first source region 110, first channel region 120, and first drain region 130 corresponding to the first semiconductor structure can be included in one memory cell string MCS, where the first semiconductor structure, the vertical bit line 210, and the vertical bit line 210, the second drain region 330, the second channel region 320, and the second source region 310 corresponding to the second semiconductor structure may be, aligned with each other in the vertical direction (Z direction), such that the first semiconductor structure, the vertical bit line 210, and the second semiconductor structure can be collinear. For example, the first source region 110, the first channel region 120, the first drain region 130, the vertical bit line 210, the second drain region 330, the second channel region 320, and the second source region 310 included in one memory cell string MCS may be aligned with each other and arranged sequentially in the vertical direction (Z direction).

In FIGS. 2A and 2B, it is illustrated that the first semiconductor structure, the vertical bit line 210, and the second semiconductor structure have substantially the same horizontal width and horizontal area, but the embodiments are not limited thereto. In various embodiments, the horizontal width and the horizontal area of the vertical bit line 210 may be greater than the horizontal width and the horizontal area of each of the first semiconductor structure and the second semiconductor structure. In various embodiments, the horizontal width and the horizontal area of the vertical bit line 210 may be less than the horizontal width and the horizontal area of each of the first semiconductor structure and the second semiconductor structure. In various embodiments, the horizontal width and the horizontal area of each of the first semiconductor structure, the vertical bit line 210, and the second semiconductor structure may gradually decrease in the vertical direction (Z direction). In various embodiments, the horizontal width and the horizontal area of each of the first semiconductor structure, the vertical bit line 210, and the second semiconductor structure may gradually increase in the vertical direction (Z direction).

In various embodiments, the semiconductor memory device 1 may further include a periphery circuit structure 900. The plurality of first source lines 100, the plurality of first vertical channel transistors LVT, the memory cell array MCA, the plurality of second vertical channel transistors UVT, and the plurality of second source lines 400 may be sequentially arranged on the periphery circuit structure 900. The combination of the plurality of first source lines 100, the plurality of first vertical channel transistors LVT, the memory cell array MCA, the plurality of second vertical channel transistors UVT, and the plurality of second source lines 400, which are arranged on the periphery circuit structure 900, may be referred to as a cell structure.

In various embodiments, the periphery circuit structure 900 may include a periphery circuit 920. The periphery circuit 920 may receive an address signal, a command signal, and a control signal from a device outside the semiconductor memory device 1, and transceive data to and from the device outside the semiconductor memory device 1. The periphery circuit 920 may include a row decoder, a page buffer, a data input/output circuit, and a control logic. In some embodiments, the periphery circuit 920 may further include an input/output interface, a column logic, a voltage generator, a pre-decoder, a temperature sensor, a command decoder, an address decoder, an amplification circuit, etc. The periphery circuit structure 900 may include a substrate on which the periphery circuit 920 is formed. The substrate may include, for example, Si, for example, crystalline Si, polycrystalline Si, or amorphous Si. Alternatively, the substrate may include at least one compound semiconductor of a semiconductor element such as germanium (Ge), silicon germanium (SiGe), silicon carbide (SiC), gallium arsenide (GaAs), indium arsenide (InAs), and indium phosphide (InP). Alternatively, the substrate may include a silicon-on-insulator (SOI) substrate or a germanium-on-insulator (GeOI) substrate, where for example, the substrate may include a buried oxide (BOX) layer. The substrate may include a conductive region, for example, a well doped with an impurity or a structure doped with an impurity.

In various embodiments, the semiconductor memory device 1 may include a second contact via 510, a third contact via 520, and a fourth contact via 530. Each of the second contact via 510, the third contact via 520, and the fourth contact via 530 may be electrically connected to the periphery circuit 920 included in the periphery circuit structure 900. In some embodiments, each of the second contact via 510, the third contact via 520, and the fourth contact via 530 may be electrically connected to different members of the periphery circuit 920 included in the periphery circuit structure 900. The second contact via 510 may be between the periphery circuit structure 900 and the first gate line 150, where the second contact via 510 may electrically connect the periphery circuit structure 900 to the first gate line 150. The third contact via 520 may be between the periphery circuit structure 900 and the first source line 100, where the third contact via 520 may electrically connect the periphery circuit structure 900 to the first source line 100. The fourth contact via 530 may be between the periphery circuit structure 900 and the second source line 400, where the fourth contact via 530 may electrically connect the periphery circuit structure 900 to the second source line 400.

In various embodiments, the second contact via 510 may be electrically connected to the first contact via 500. In some embodiments, the first contact via 500 and the second contact via 510 related to each other may be formed in one body but are not limited thereto. For example, the first contact via 500 and the second contact via 510 may be formed separately from each other, so that the first contact via 500 is arranged between the first gate line 150 and the second gate line 350, and the second contact via 510 is arranged between the first gate line 150 and the periphery circuit structure 900.

In various embodiments, the third contact via 520 may be electrically connected to the first source line 100 and the periphery circuit structure 900. The fourth contact via 530 may be electrically connected to the second source line 400 and the periphery circuit structure 900.

In various embodiments, the first gate line 150 and the second gate line 350 associated with to each other may be equipotential by being electrically connected to each other via the first contact via 500, and may be electrically connected to the periphery circuit structure 900 via the second contact via 510. On the other hand, the first source line 100 and the second source line 400 associated with to each other may be electrically connected to the periphery circuit structure 900 via the third contact via 520 and the fourth contact via 530, respectively, and may have independent voltages. For example, by the periphery circuit 920 included in the periphery circuit structure 900, the first source line 100 and the second source line 400 associated with each other may also be equipotential, however, may have different voltages from each other.

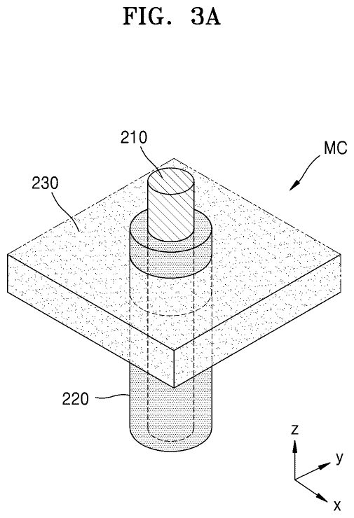

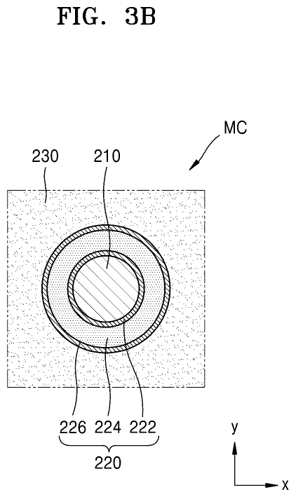

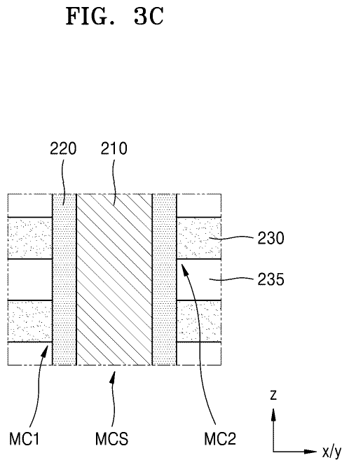

FIGS. 3A through 3C are diagrams of the memory cell MC and the memory cell string MCS, according to embodiments. FIG. 3A is a perspective view of the memory cell MC, FIG. 3B is a planar cross-sectional view of the memory cell MC, and FIG. 3C is a vertical cross-section view illustrating a portion of the memory cell string MCS.

Referring to FIGS. 3A through 3C together, the memory cell MC may include the vertical bit line 210, the word line plate 230, and the selector 220 arranged between the vertical bit line 210 and the word line plate 230. The memory cell string MCS may include the plurality of memory cells MC, for example, a first memory cell MC1 and a second memory cell MC2 arranged in the vertical direction (Z direction). It is illustrated that in FIG. 3C, the memory cell string MCS includes two memory cells MC, that is, the first memory cell MC1 and the second memory cell MC2, however, the embodiment is an example and is not limited thereto. For example, the memory cell string MCS may include the plurality of memory cell strings MCS corresponding to the number of word line plates 230.

A plurality of insulating layers 235 may fill between each of the plurality of word line plates 230. For example, the plurality of word line plates 230 and the plurality of insulating layers 235 may be alternately arranged in the vertical direction (Z direction), to form a stacked structure of the plurality of word line plates 230 and the plurality of insulating layers 235, which may be referred to as a word line structure. The vertical bit line 210 may extend through the word line structure, where a stacked structure, in which the plurality of word line plates 230 and the plurality of insulating layers 235 are alternately stacked in the vertical direction (Z direction), and may be formed in the vertical direction (Z direction). In various embodiments, each of the plurality of insulating layers 235 may include silicon oxide or an insulating material having a lower dielectric constant than silicon oxide. In some embodiments, each of the plurality of insulating layers 235 may include a tetraethyl orthosilicate (TEOS) layer or an ultra-low dielectric constant K (ULK) layer with an ULK of about 2.2 to about 2.4. The ULK layer may include a SiOC layer or a SiCOH layer.

In various embodiments, a portion of the selector 220, which is arranged between the vertical bit line 210 and the word line plate 230, and forming a memory cell MC, may be referred to as a selected factor. The memory cell MC may include the vertical bit line 210, the word line plate 230, and the selected factor which is a portion of the selector 220 arranged between the vertical bit line 210 and the word line plate 230. For example, one memory cell string MCS may include a plurality of selected factors, which are portions of the selectors 220 corresponding to the number of word line plates 230. In some embodiments, each of the plurality of selected factors may include the selectors 220 spaced apart from each other in the vertical direction (Z direction). For example, one memory cell string MCS may include the selectors 220 corresponding to the number of word line plates 230.

In various embodiments, the selector 220 may include a first selected electrode layer 222, a selected substance layer 224, and a second selected electrode layer 226, as shown in FIG. 3B. The first selected electrode layer 222 may be arranged between the vertical bit line 210 and the selected substance layer 224, and the second selected electrode layer 226 may be arranged between the word line plate 230 and the selected substance layer 224, where the selected substance layer 224 can be annularly between the first selected electrode layer 222 and the second selected electrode layer 226. In some embodiments, the first selected electrode layer 222 may extend along the plurality of word line plates 230 surrounding the vertical bit line 210 in the vertical direction (Z direction) and surround the vertical bit line 210, but is not limited thereto. For example, the first selected electrode layer 222 included in one memory cell string MCS may be arranged between the vertical bit line 210 and each of the plurality of word line plates 230 surrounding the vertical bit line 210, and the first selected electrode layer 222 may be arranged in plural and spaced apart from each other in the vertical direction (Z direction). The second selected electrode layer 226 included in one memory cell string MCS may be arranged between each of the plurality of word line plates 230 and the selected substance layer 224, and may be in plural and spaced apart from each other.

Each of the first selected electrode layer 222 and the second selected electrode layer 226 may include a conductive material, for example, carbon or a conductive substance including carbon. The selected substance layer 224 may include a substance having ovonic threshold switching (OTS) characteristics. The selected substance layer 224 may include chalcogenide substance. For example, the selected substance layer 224 may include a sing layer or a multi-layer including one of two-component substances, such as GeSe, GeS, AsSe, AsTe, AsS, SiTe, SiSe, SiS, GeAs, SiAs, SnSe, and SnTe, three-component substances, such as GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe, four-component substances, such as GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, and GeAsTeZn, five-component substances, such as GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, and GeAsSeZnSn, and six-component substances, such as GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn. In some embodiments, each selected substance layer 224 may include at least one substance of the two-through six-component substances described above, and at least one additional element of boron (B), carbon (C), nitrogen (N), and oxygen (O).

When the selector 220 includes a substance having OTS characteristics and a voltage equal to or greater than a threshold voltage (Vₜₕ) is applied to both ends of the selector 220, resistance or the threshold voltage Vₜₕ in the selector 220 may be rapidly reduced due to a threshold switching phenomenon and the selector 220 may be in a turn-on state in which a current flows. In this manner, when the selector 220 is in the turn-on state, and a current equal to or less than a particular threshold flows therein, the resistance or the threshold voltage (Vₜₕ) may rapidly increase again, and the selector 220 may be in a turn-off state, in which a current rarely flows, and the turn-on state and the turn-off state may respectively correspond to different logic states (a SET state and a RESET state).

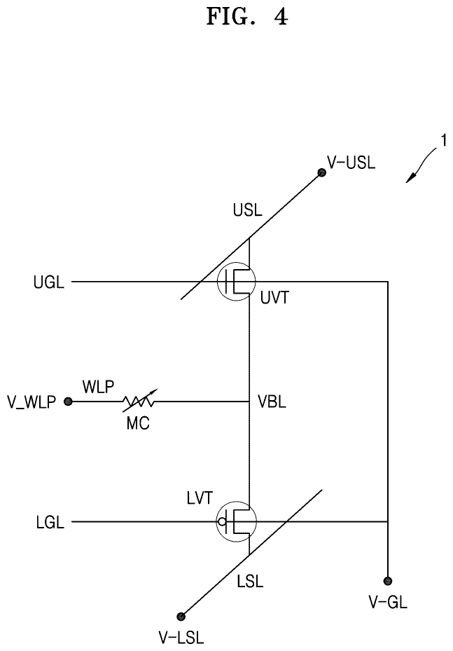

FIG. 4 is an equivalent circuit diagram of the semiconductor memory device 1 according to an embodiment.

Referring to FIG. 4, the semiconductor memory device 1 may include a first source line LSL, a second source line USL, a vertical bit line VBL arranged between the first source line LSL and the second source line USL, the first vertical channel transistor LVT arranged between the first source line LSL and the vertical bit line VBL, the second vertical channel transistor UVT arranged between the second source line USL and the vertical bit line VBL, a word line plate WLP arranged between the first vertical channel transistor LVT and the second vertical channel transistor UVT, and the memory cell MC constituted between the vertical bit line VBL and the word line plate WLP. A first gate line LGL may be connected to a gate of the first vertical channel transistor LVT, and a second gate line UGL may be connected to a gate of the second vertical channel transistor UVT.

In various embodiments, the first source line LSL, the second source line USL, the vertical bit line VBL, the memory cell MC, the first vertical channel transistor LVT, the second vertical channel transistor UVT, the word line plate WLP, the first gate line LGL, and the second gate line UGL may correspond to the first source line 100, the second source line 400, the vertical bit line 210, the memory cell MC, the first vertical channel transistor LVT, the second vertical channel transistor UVT, the word line plate 230, the first gate line 150, and the second gate line 350, as illustrated in FIGS. 1 through 3C, respectively. It is shown in FIG. 4, for convenience of illustration, one memory cell MC arranged between the word line plate WLP and the vertical bit line VBL, between the first vertical channel transistor LVT and the second vertical channel transistor UVT; however, the embodiment is not limited thereto, and a plurality of word line plates WLP may be arranged between the first vertical channel transistor LVT and the second vertical channel transistor UVT and a plurality of memory cells MC may be respectively arranged between a plurality of word line plates WLP and the vertical bit line VBL.

In various embodiments, a first source voltage V-LSL may be provided to the first source line LSL, and a second source voltage V-USL may be provided to the second source line USL. The first source voltage V-LSL may be referred to as a lower source voltage, and the second source voltage V-USL may be referred to as an upper source voltage. A word line plate voltage V-WLP may be supplied to the word line plate WLP. A gate voltage V-GL may be commonly supplied to the first gate line LGL and the second gate line UGL.

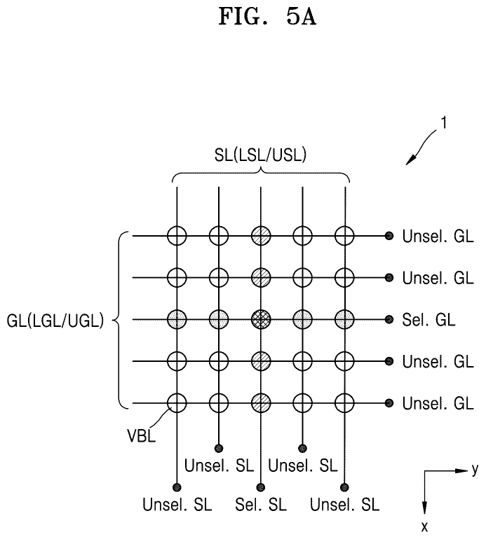

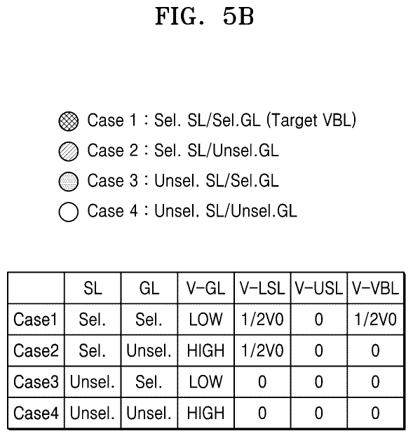

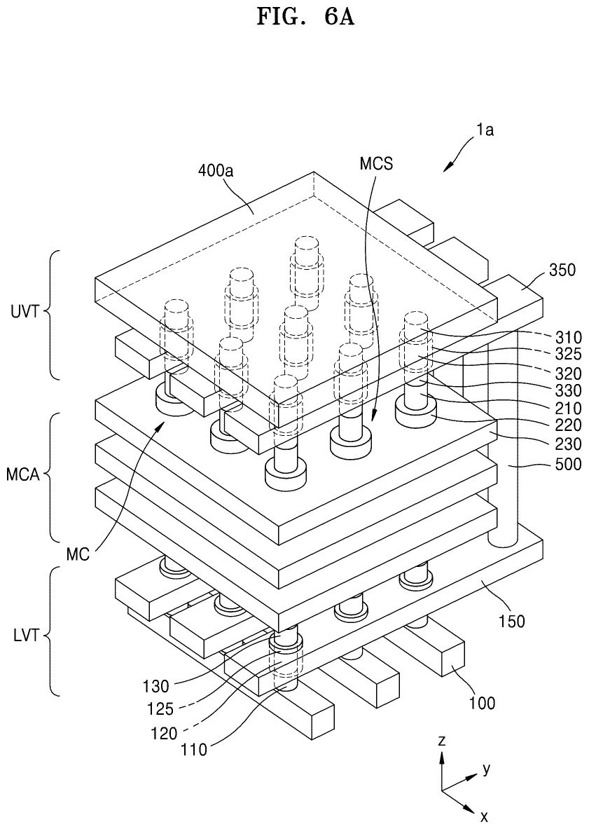

FIGS. 5A and 5B are diagrams for describing operations of the semiconductor memory device 1, according to embodiments. FIGS. 5A and 5B conceptually illustrate a plate corresponding to one word line plate 230 illustrated in FIGS. 1 through 3C.

Referring to FIGS. 4, 5A, and 5B together, in the semiconductor memory device 1, one source line SL may be selected as, hereinafter, a selected source line Sel. A source line SL among a plurality of source lines SL, each including the first source line LSL and the second source line USL, associated with each other, may be selected, where the remaining source lines SL may be unselected, as referred to hereinafter, as unselected source lines Unsel. SL.A gate line GL among a plurality of gate lines GL, each including the first gate line LGL and the second gate line UGL, and the remaining gate lines GL may be unselected, as referred to hereinafter, as unselected gate lines Unsel. GL. The vertical bit line VBL arranged at a portion, at which the selected source line Sel. SL crosses the selected gate line Sel. GL, may include a target vertical bit line Target VBL (Case 1). On the periphery of the target vertical bit line Target VBL, the vertical bit line VBL arranged at a portion, where the selected source line Sel. SL crosses the unselected gate line Unsel. GL (Case 2), the vertical bit line VBL arranged at a portion, where the unselected source line Unsel. SL crosses the selected source line Sel. SL (Case 3), and the vertical bit line VBL arranged at a portion where the unselected source line Unsel. SL crosses the unselected gate line Unsel. GL (Case 4) may be arranged.

In various embodiments, the gate voltage V-GL supplied to the selected gate line Sel. GL may be ‘LOW’, and the gate voltage V-GL supplied to the unselected gate line Unsel. GL may be ‘HIGH’. The first source voltage V-LSL supplied to the first source line LSL of the selected source line Sel. SL may be ‘1/2V0’, and the second source voltage V-USL supplied to the second source line USL of the selected source line Sel. SL may be ‘0’. The first source voltage V-LSL supplied to the first source line LSL of the unselected source line Unsel. SL may be ‘0’, and the second source voltage V-USL supplied to the second source line USL of the unselected source line Unsel. SL may be ‘0’. A bit line voltage V-VBL supplied to the target vertical bit line Target VBL may be ‘1/2V0’ (Case 1), and the bit line voltage V-VBL supplied to other vertical bit lines VBL may be ‘0’ (Case 2, Case 3, and Case 4).

The second source voltage V-USL supplied to the second source line USL of the selected source line Sel. SL and the second source voltage V-USL supplied to the second source line USL of the unselected source line Unsel. SL may be identically ‘0’, and the first source voltage V-LSL supplied to the first source line LSL of the selected source line Sel. SL may be different from the first source voltage V-LSL supplied to the first source line LSL of the unselected source line Unsel. SL. In other words, the identical second source voltage V-USL may be supplied to the second source line USL regardless of whether the second source line USL is selected/unselected, and by the first source voltage V-LSL supplied to the first source line LSL, the whether the first source line LSL is selected/unselected may be determined.

In the semiconductor memory device 1 according to the inventive concept, because a voltage of ‘0’, that is, ground, is connected to other vertical bit lines VBL except for the target vertical bit line Target VBL, a floating phenomenon on other vertical bit lines VBL, except for the target vertical bit line, Target VBL, may be prevented, and thus, the operation reliability of the semiconductor memory device 1 may be improved.

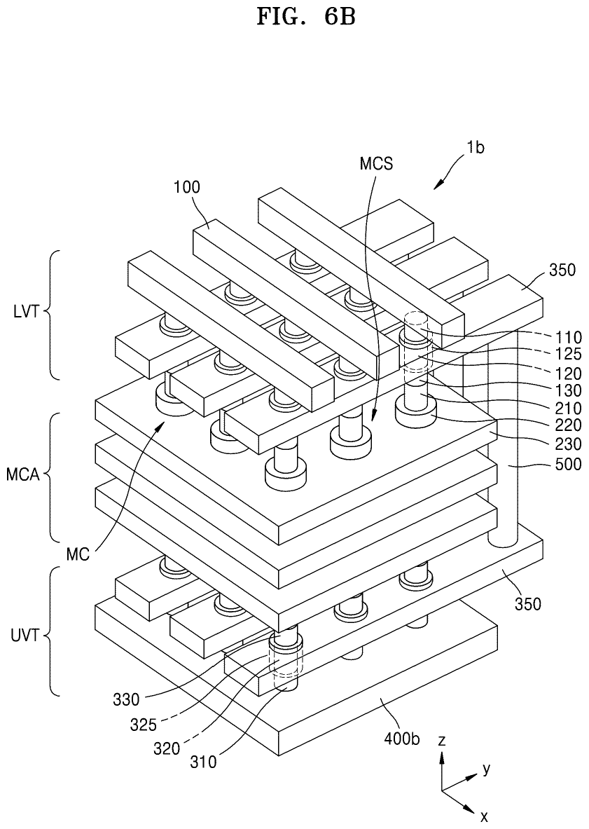

FIGS. 6A and 6B are perspective views of semiconductor memory devices 1a and 1b, respectively, according to embodiments.

Referring to FIG. 6A, the semiconductor memory device 1a may include the plurality of first source lines 100, a second source line 400a, the memory cell array MCA arranged between the plurality of first source lines 100 and the second source line 400a, and including the plurality of memory cell strings MCS, the plurality of first vertical channel transistors LVT arranged between the plurality of first source lines 100 and the memory cell array MCA, and the plurality of second vertical channel transistors UVT arranged between the second source line 400a and the memory cell array MCA.

In various embodiments, the plurality of first source lines 100 may extend in parallel with each other in the first horizontal direction (X direction), and be arranged apart from each other in the second horizontal direction (Y direction). The second source line 400a may be spaced apart from the plurality of first source lines 100 in the vertical direction (Z direction) and arranged on the plurality of first source lines 100. The second source line 400a may have a flat plate shape (e.g., rectangular prism) extending in each of the first horizontal direction (X direction) and the second horizontal direction (Y direction). Referring to descriptions given with reference to FIGS. 5A and 5B, because the identical second source voltage V-USL is supplied to the second source line USL regardless of whether the second source line USL is selected/unselected, the first source line LSL may have one flat plate shape extending in each of the first horizontal direction (X direction) and the second horizontal direction (Y direction), and because a different first source voltage V-LSL is supplied to the first source line LSL according to whether the first source line LSL is selected/unselected, the second source line 400a corresponding to the plurality of first source lines 100 may have a flat plate shape.

Referring to FIG. 6B, the semiconductor memory device lb may include a second source line 400b, the plurality of first source lines 100, the memory cell array MCA arranged between the plurality of first source lines 100 and the second source line 400b and including the plurality of memory cell strings MCS, the plurality of second vertical channel transistors UVT arranged between the second source line 400b and the memory cell array MCA, and the plurality of first vertical channel transistors LVT arranged between the plurality of first source lines 100 and the memory cell array MCA. The semiconductor memory device lb illustrated in FIG. 6B may have a vertically inverted form of the semiconductor memory device la illustrated in FIG. 6A, and duplicate descriptions thereof are omitted.

In various embodiments, the second source line 400b may have a flat plate shape extending in each of the first horizontal direction (X direction) and the second horizontal direction (Y direction). The plurality of first source lines 100 may extend in parallel with each other in the first horizontal direction (X direction), and be arranged spaced apart from each other in the second horizontal direction (Y direction). The plurality of first source lines 100 may be spaced apart from the second source line 400b in the vertical direction (Z direction) and arranged on the second source line 400b.

In various embodiments, the plurality of second vertical channel transistors UVT may be arranged on the second source line 400b, and the plurality of first vertical channel transistors LVT may be arranged under the plurality of first source lines 100, where the first vertical channel transistors LVT may be proximal to the first source lines 100. The memory cell array MCA may be arranged between the plurality of second vertical channel transistors UVT and the plurality of first vertical channel transistors LVT.

Referring to descriptions given with reference to FIGS. 5A and 5B, because the identical second source voltage V-USL is supplied to the second source line USL regardless of whether to be selected/unselected, the first source line LSL may have one flat plate shape extending in each of the first horizontal direction (X direction) and the second horizontal direction (Y direction), and because a different first source voltage V-LSL is supplied to the first source line LSL according to whether to be selected/unselected, the second source line 400b corresponding to the plurality of first source lines 100 may have one flat plate shape.

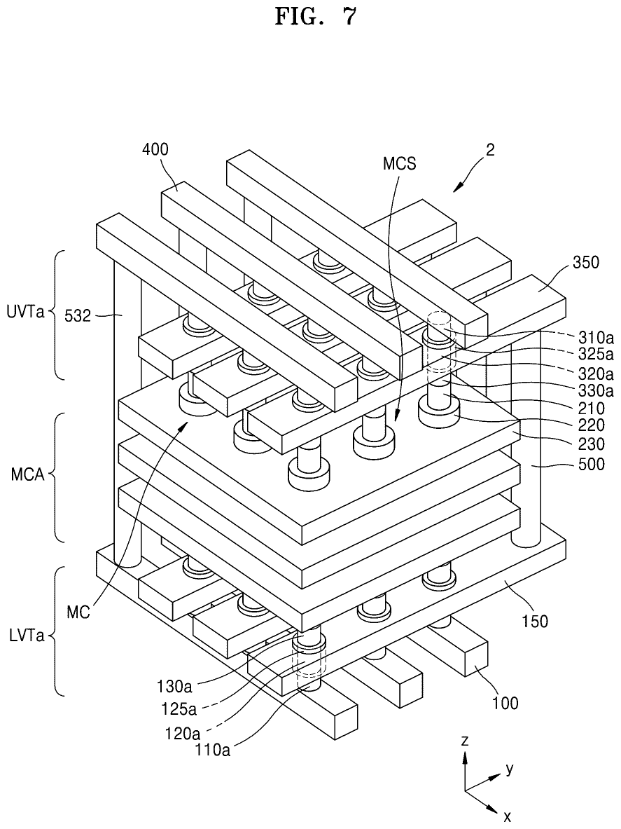

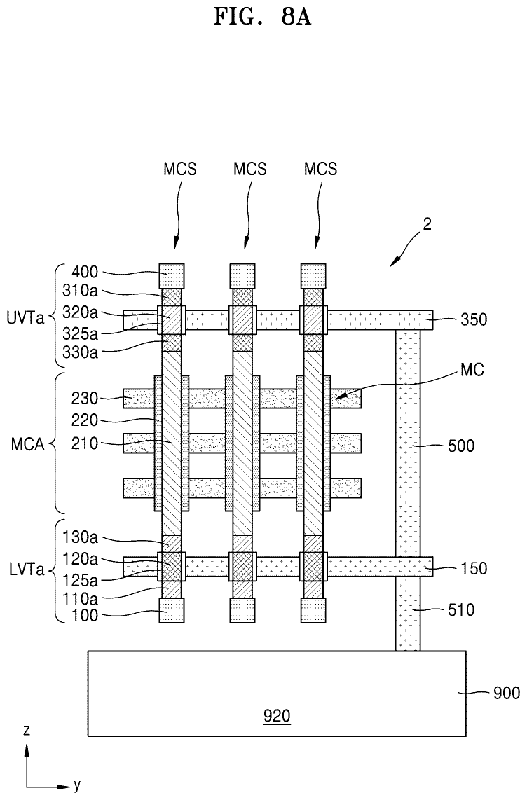

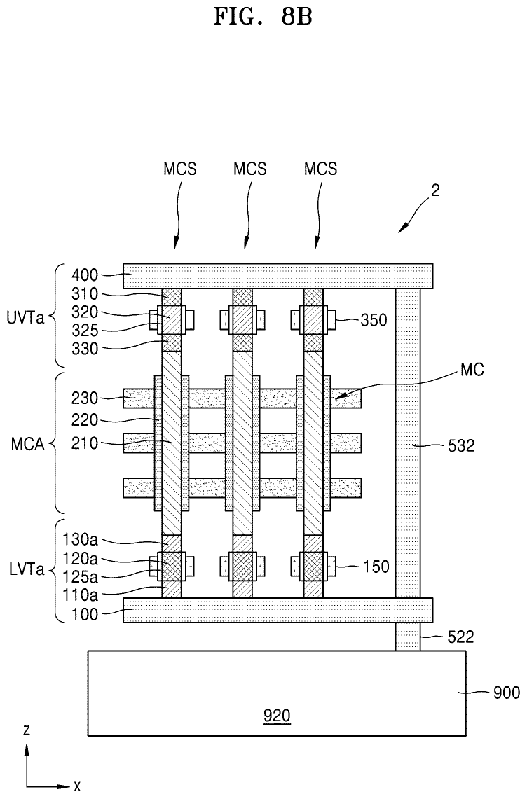

FIG. 7 is a perspective view of a semiconductor memory device 2 according to an embodiment, and FIGS. 8A and 8B are vertical cross-section views of the semiconductor memory device 2 according to embodiments.

Referring to FIGS. 7, 8A, and 8B, the semiconductor memory device 2 may include the plurality of first source lines 100, the plurality of second source lines 400, the plurality of memory cell strings MCS arranged between the plurality of first source lines 100 and the plurality of second source lines 400, the plurality of first vertical channel transistors LVT arranged between the plurality of first source lines 100 and the plurality of second source lines 400, and the plurality of second vertical channel transistors UVTa arranged between the plurality of second source lines 400 and the plurality of memory cell strings MCS.

In various embodiments, the memory cell string MCS may include the plurality of memory cells MC. The plurality of memory cell strings MCS may constitute the memory cell array MCA, where the memory cells MC may be arranged as an X-Y array. The memory cell array MCA may be arranged between a plurality of first vertical channel transistors LVTa and the plurality of second vertical channel transistors UVTa. The first vertical channel transistor LVTa may be referred to as a lower vertical channel transistor, and the second vertical channel transistor UVTa may be referred to as an upper vertical channel transistor.

In various embodiments, the plurality of first vertical channel transistors LVTa may include a plurality of first source regions 110a, a plurality of first channel regions 120a, a plurality of first drain regions 130a, the plurality of first gate lines 150, and a plurality of first gate insulating layers 125a arranged between the plurality of first channel regions 120a and the plurality of first gate lines 150. The first source region 110a may be referred to as a lower source region, the first channel region 120a may be referred to as a lower channel region, the first gate insulating layer 125a may be referred to as a lower gate insulating layer, the first drain region 130a may be referred to as a lower drain region, and the first gate line 150 may be referred to as a lower gate line.

In various embodiments, the first source region 110a, the first channel region 120a, the first drain region 130a, the first gate line 150, and the first gate insulating layer 125a may constitute the first vertical channel transistor LVTa. The first source region 110a, the first channel region 120a, and the first drain region 130 may be sequentially arranged in the vertical direction (Z direction), where the first channel region 120a can be between the first source region 110a and the first drain region 130a. The first source region 110a, the first channel region 120a, and the first drain region 130a may be referred to as a first semiconductor structure.

In various embodiments, the plurality of second vertical channel transistors UVTa may include a plurality of second source regions 310a, a plurality of second channel regions 320a, a plurality of second drain regions 330a, a plurality of second gate lines 350, and a plurality of second gate insulating layers 325a arranged between the plurality of second channel regions 320a and the plurality of second gate lines 350. The second source region 310a may be referred to as an upper source region, the second channel region 320a may be referred to as an upper channel region, the second gate insulating layer 325a may be referred to as an upper gate insulating layer, the second drain region 330a may be referred to as an upper drain region, and the second gate line 350 may be referred to as an upper gate line. The second source regions 310a, adjoining second channel regions 320a, adjoining second drain region 330a may be collinear with each other and with a corresponding vertical bit line 210.

In various embodiments, the second source region 310a, the second channel region 320a, the second drain region 330a, the second gate line 350, and the second gate insulating layer 325a may constitute the second vertical channel transistor UVTa. The second drain region 330a, the second channel region 320a, and the second source region 310a associated with each other may be sequentially arranged in the vertical direction (Z direction), where the second channel region 320a can be between the second source region 310a and the second drain region 330a. The second drain region 330a, the second channel region 320a, and the second source region 310a associated with each other may be referred to as a second semiconductor structure.

In various embodiments, each of the first source region 110a, the first drain region 130a, the second source region 310a, and the second drain region 330a may include a second conductivity type, and each of the first channel region 120a and the second channel region 320a may include a first conductivity type that is different from the second conductivity type. In various embodiments, each of the first vertical channel transistor LVTa and the second vertical channel transistor UVTa may include an n-type MOSFET. In various other embodiments, each of the first source region 110a, the first drain region 130a, the second source region 310a, and the second drain region 330a may include a first conductivity type, and each of the first channel region 120a and the second channel region 320a may include a second conductivity type that is different from the first conductivity type. In various embodiments, each of the first vertical channel transistor LVTa and the second vertical channel transistor UVTa may include a p-type MOSFET. The first vertical channel transistor LVTa and the second vertical channel transistor UVTa may include a MOSFET of the same type.

In various embodiments, the semiconductor memory device 2 may further include the periphery circuit structure 900. The periphery circuit structure 900 may include the periphery circuit 920. The plurality of first source lines 100, the plurality of first vertical channel transistors LVTa, the memory cell array MCA, the plurality of second vertical channel transistors UVTa, and the plurality of second source lines 400 may be sequentially arranged on the periphery circuit structure 900. The plurality of first source lines 100, the plurality of first vertical channel transistors LVTa, the memory cell array MCA, the plurality of second vertical channel transistors UVTa, and the plurality of second source lines 400, which are arranged on the periphery circuit structure 900, may be referred to as a cell structure.

In various embodiments, the semiconductor memory device 2 may include the first contact via 500, the second contact via 510, a third contact via 522, and a fourth contact via 532. The first contact via 500 may electrically connect the first gate line 150 to the second gate line 350. The first gate line 150 and the second gate line 350 may be electrically connected to each other via the first contact via 500 to be equipotential. The second contact via 510 and the third contact via 522 may be electrically connected to the periphery circuit structure 900. Each of the second contact via 510 and the third contact via 522 may be electrically connected to the periphery circuit 920 included in the periphery circuit structure 900. In various embodiments, each of the second contact via 510 and the third contact via 522 may be electrically connected to different members of the periphery circuit 920 included in the periphery circuit structure 900.

In various embodiments, the second contact via 510 may be electrically connected to the first contact via 500. The third contact via 522 may be electrically connected to the first source line 100 and the periphery circuit structure 900. The fourth contact via 532 may electrically connect the second source line 400 to the first source line 100. The first source line 100 and the second source line 400 may be electrically connected to each other via the fourth contact via 532 to be equipotential.

In various embodiments, the first gate line 150 and the second gate line 350 corresponding to each other may be equipotential by being electrically connected to each other via the first contact via 500, and may be electrically connected to the periphery circuit structure 900 via the second contact via 510. The first source line 100 and the second source line 400 may be equipotential by being electrically connected to each other via the fourth contact via 532, and may be electrically connected to the periphery circuit structure 900 via the third contact via 522 to have an independent voltage.

In various embodiments, the third contact via 522 and the fourth contact via 532 may be formed in one body but are not limited thereto. For example, the third contact via 522 and the fourth contact via 532 may be formed separately from each other, so that the fourth contact via 532 is arranged between the first gate line 150 and the second gate line 350, and the third contact via 522 is arranged between the first gate line 150 and the periphery circuit structure 900.

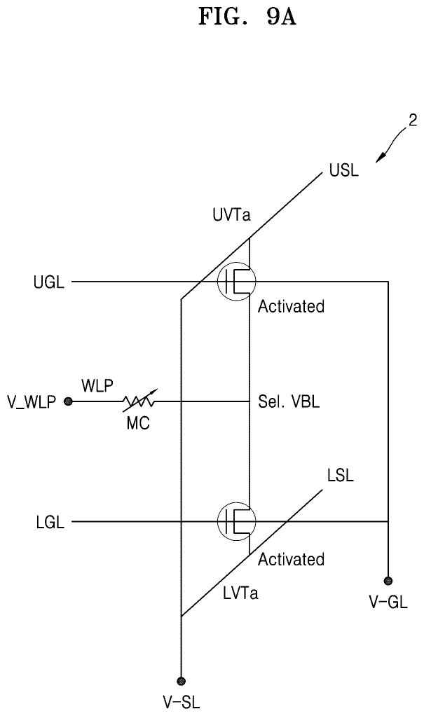

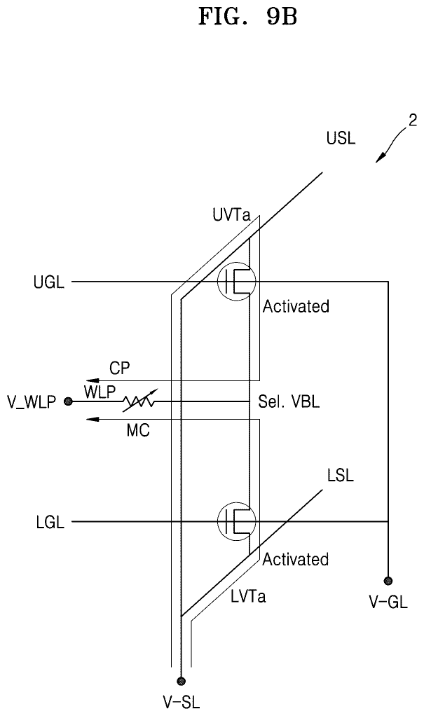

FIGS. 9A and 9B are diagrams for describing operations of a semiconductor memory device 2, according to embodiments.

Referring to FIG. 9A, the semiconductor memory device 2 may include the first source line LSL, the second source line USL, the vertical bit line VBL arranged between and electrically connected to the first source line LSL and the second source line USL, the first vertical channel transistor LVTa arranged between the first source line LSL and the vertical bit line VBL, the second vertical channel transistor UVTa arranged between the second source line USL and the vertical bit line VBL, the word line plate WLP arranged between the first vertical channel transistor LVTa and the second vertical channel transistor UVTa, and the memory cell MC between the vertical bit line VBL and the word line plate WLP. The first gate line LGL may be connected to a gate of the first vertical channel transistor LVTa, and the second gate line UGL may be connected to a gate of the second vertical channel transistor UVTa.

In various embodiments, the first source line LSL, the second source line USL, the vertical bit line VBL, the memory cell MC, the first vertical channel transistor LVTa, the second vertical channel transistor UVTa, the word line plate WLP, the first gate line LGL, and the second gate line UGL may correspond to the first source line 100, the second source line 400, the vertical bit line 210, the memory cell MC, the first vertical channel transistor LVTa, the second vertical channel transistor UVTa, the word line plate 230, the first gate line 150, and the second gate line 350 illustrated in FIGS. 7 through 8B, respectively.

A source voltage V-SL may be commonly supplied to the first source line LSL and the second source line USL. The word line plate voltage V-WLP may be supplied to the word line plate WLP. The gate voltage V-GL may be commonly supplied to the first gate line LGL and the second gate line UGL. When the first vertical channel transistor LVTa and the second vertical channel transistor UVTa are activated by the source voltage V-SL, the vertical bit line VBL connected to the activated first vertical channel transistor LVTa and second vertical channel transistor UVTa, hereinafter, a selected vertical bit line Sel. VBL may be selected.

Referring to FIG. 9B, when the first vertical channel transistor LVTa and the second vertical channel transistor UVTa are activated by the source voltage V-SL, a voltage and current may be applied to the selected vertical bit line Sel. VBL, and a current path CP from each of the first vertical channel transistor LVTa and the second vertical channel transistor UVTa to the memory cell MC may be generated. Accordingly, because the current supplied to the memory cell MC is supplied from each of the first vertical channel transistor LVTa and the second vertical channel transistor UVTa, the on-current of the memory cell MC may be about twice as much as the case of a current supplied from one vertical channel transistor.

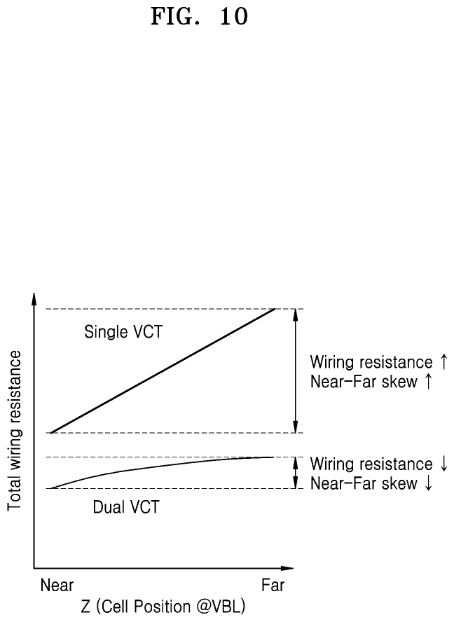

FIG. 10 is a diagram for describing characteristics of the semiconductor memory device 2 according to an embodiment.

Referring to FIGS. 7 through 10 together, FIG. 10 illustrates total wiring resistances according to a position of the memory cell MC Z (cell position @VBL) on the vertical bit line VBL in the vertical direction (Z direction) for a comparison example, in which one vertical channel transistor (VCT), or a single VCT, is included, and for an embodiment of the inventive concept, in which two vertical channel transistors or a dual VCT, for example, the first vertical channel transistor LVTa and the second vertical channel transistor UVTa, are included.

In the comparison example with one vertical channel transistor or a single VCT, the wiring resistance may continuously increase, as the position of the memory cell MC moves far away from the vertical bit line VBL in the vertical direction (Z direction), and thus, the near-far skew according to the position difference of the memory cell MC may increase. In various embodiments with two vertical channel transistors or a dual VCT, although the position of the memory cell MC becomes far from the vertical bit line VBL in the vertical direction (Z direction), the wiring resistance may increase relatively less, and thus, the near-far skew according to the position difference of the memory cell MC may decrease.

Accordingly, because the near-far skew of the memory cells MC in the memory cell array MCA may be reduced, the operation reliability of the semiconductor memory device 2 may be improved, and because the number of the memory cells MC included in the memory cell string MCS arranged in the vertical direction (Z direction) may be increased, the memory capacity of the semiconductor memory device 2 may be increased.

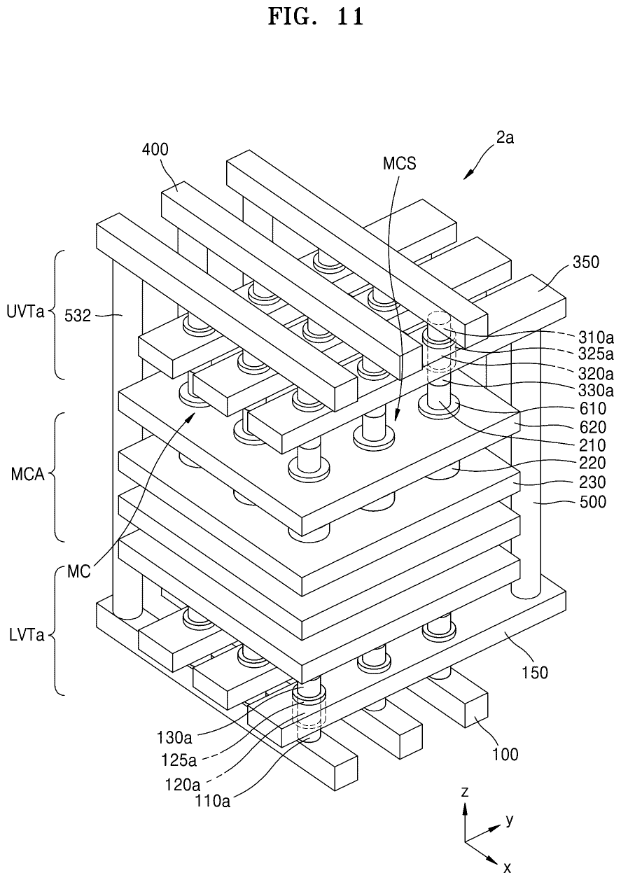

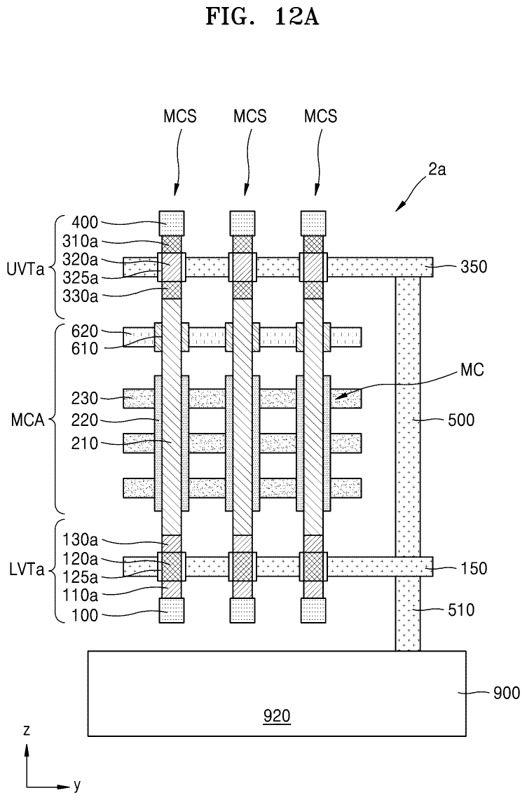

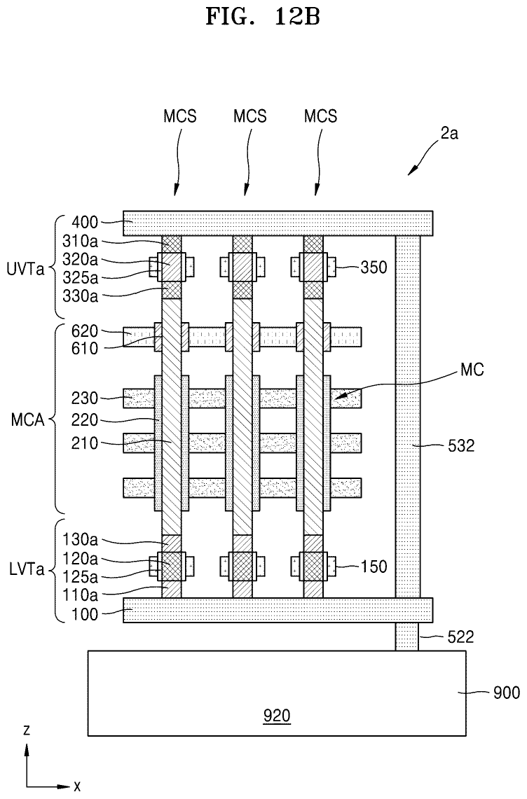

FIG. 11 is a perspective view of a semiconductor memory device 2a according to an embodiment, and FIGS. 12A and 12B are vertical cross-section views of the semiconductor memory device 2a, according to embodiments.

Referring to FIGS. 11, 12A, and 12B together, the semiconductor memory device 2a may include the plurality of first source lines 100, the plurality of second source lines 400, the plurality of memory cell strings MCS arranged between the plurality of first source lines 100 and the plurality of second source lines 400, a plurality of first vertical channel transistors LVTa arranged between the plurality of first source lines 100 and the plurality of memory cell strings MCS, the plurality of second vertical channel transistors UVTa arranged between the plurality of second source lines 400 and the plurality of memory cell strings MCS, a conductive plate 620 arranged between the plurality of second vertical channel transistors UVTa and the plurality of memory cell strings MCS, and a plurality of resistors 610 arranged between the conductive plate 620 and the plurality of vertical bit lines 210. The semiconductor memory device 2a illustrated in FIGS. 11, 12A, and 12B may further include the plurality of resistors 610 and the conductive plate 620, compared to the semiconductor memory device 2 illustrated in FIGS. 7, 8A, and 8B, and thus, duplicate descriptions thereof may be omitted.

In various embodiments, the conductive plate 620 may have a flat plate shape extending in each of the first horizontal direction (X direction) and the second horizontal direction (Y direction). The conductive plate 620 may be arranged spaced apart from each of the plurality of word line plates 230 and the plurality of second gate lines 350 in the vertical direction (Z direction), between the plurality of word line plates 230 and the plurality of second gate lines 350. The plurality of vertical bit lines 210 may penetrate the conductive plate 620.

In various embodiments, the plurality of resistors 610 may surround at least a portion of the plurality of vertical bit lines 210. In a plan view, the resistor 610 may have a ring shape surrounding the vertical bit line 210 corresponding thereto. In various embodiments, the resistor 610 may have a circular ring shape in a plan view, but is not limited thereto, and the shape of the resistor 610 in a plan view may be determined according to the shape of the vertical bit line 210. For example, when the vertical bit line 210 has a rectangular pillar shape, in a plan view, the shape of the resistor 610 may have a rectangular ring shape. The resistor 610 may include a high resistance substance such as oxide. For example, the resistor 610 may include a thin layer including oxide.

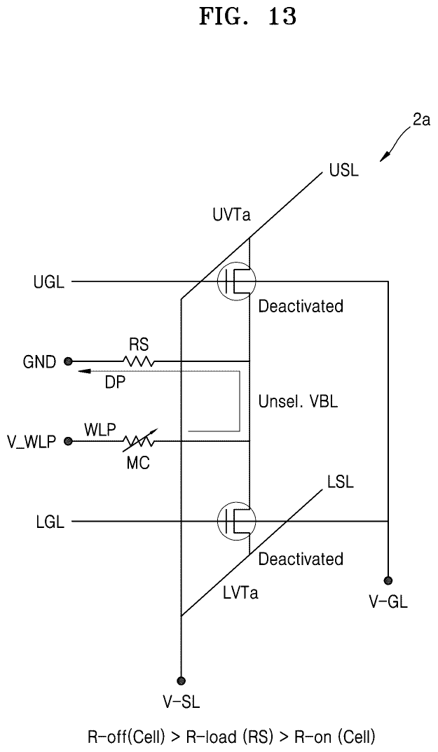

FIG. 13 is an equivalent circuit diagram for describing an operation of the semiconductor memory device 2, according to an embodiment.

Referring to FIGS. 11 through 13 together, the semiconductor memory device 2a may include the first source line LSL, the second source line USL, the vertical bit line VBL arranged between the first source line LSL and the second source line USL, the first vertical channel transistor LVTa arranged between the first source line LSL and the vertical bit line VBL, the second vertical channel transistor UVTa arranged between the second source line USL and the vertical bit line VBL, the word line plate WLP arranged between the first vertical channel transistor LVTa and the second vertical channel transistor UVTa, the memory cell MC constituted between the vertical bit line VBL and the word line plate WLP, and a resistor RS arranged between the second vertical channel transistor UVTa and the word line plate WLP. The first gate line LGL may be connected to the gate of the first vertical channel transistor LVTa, and the second gate line UGL may be connected to the gate of the second vertical channel transistor UVTa.

In various embodiments, the first source line LSL, the second source line USL, the vertical bit line VBL, the memory cell MC, the first vertical channel transistor LVTa, the second vertical channel transistor UVTa, the word line plate WLP, the first gate line LGL, the second gate line UGL, and the resistor RS may correspond to the first source line 100, the second source line 400, the vertical bit line 210, the memory cell MC, the first vertical channel transistor LVTa, the second vertical channel transistor UVTa, the word line plate 230, the first gate line 150, the second gate line 350, and the resistor 610 illustrated in FIGS. 11 through 12B, respectively.

When the first vertical channel transistor LVTa and the second vertical channel transistor UVTa are deactivated by the source voltage V-SL, the vertical bit line VBL connected to the activated first vertical channel transistor LVTa and second vertical channel transistor UVTa, hereinafter, an unselected vertical bit line Unsel. VBL, may be unselected. The resistor RS may be connected to a ground GND. For example, the ground GND may be provided to the conductive plate 620.

In the memory cell MC connected to the unselected vertical bit line Unsel. VBL, a current dissipation path DP connected to the resistor RS connected to the ground GND may be generated. For example, the resistance of the resistor RS R-load(RS) may be less than the resistance of the selector 220 of the turned off memory cell MC R-off(Cell), which is connected to the unselected vertical bit line Unsel. VBL, and may be greater than the resistance of the selector 220 of the turned-on memory cell MC R-on (Cell), which is connected to the selected vertical bit line (for example, Sel. VBL illustrated in FIGS. 9A and 9B).

In the semiconductor memory device 2a according to the inventive concept, because the current DP connected to the resistor RS connected to the ground GND may be generated in the memory cell MC connected to the unselected vertical bit line Unsel. VBL, the floating in the unselected vertical bit line Unsel. VBL may be prevented, and therefore, the operation reliability of the semiconductor memory device 2a may be improved.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a first source line extending in a first horizontal direction;
a second source line extending in the first horizontal direction;
a plurality of word line plates arranged apart from each other in a vertical direction, between the first source line and the second source line;
a vertical bit line extending through the plurality of word line plates in the vertical direction;
a selector arranged between the plurality of word line plates and the vertical bit line;
a first vertical channel transistor between the vertical bit line and the first source line; and
a second vertical channel transistor between the vertical bit line and the second source line.

2. The semiconductor memory device of claim 1,
wherein the first vertical channel transistor comprises a first source region, a first channel region, a first drain region, which are sequentially arranged from the first source line to the vertical bit line, a first gate line surrounding the first channel region, wherein the first gate line extends in a second horizontal direction different from the first horizontal direction, and a first gate insulating layer separating the first channel region from the first gate line, and
wherein the second vertical channel transistor comprises a second source region, a second channel region, a second drain region, which are sequentially arranged from the second source line to the vertical bit line, a second gate line surrounding the second channel region, wherein the second gate line extends in the second horizontal direction, and a second gate insulating layer separating the second channel region from the second gate line.

3. The semiconductor memory device of claim 2, further comprising a first contact via extending in the vertical direction, and electrically connecting the first gate line to the second gate line.

4. The semiconductor memory device of claim 1, wherein the first vertical channel transistor and the second vertical channel transistor comprise metal-oxide semiconductor field effect transistors (MOSFETs) of different types.

5. The semiconductor memory device of claim 4, further comprising:
a periphery circuit structure arranged under the first source line, and surrounding a periphery circuit;
a second contact via electrically connecting the first source line to the periphery circuit structure, and extending in the vertical direction; and
a third contact via electrically connect the second source line to the periphery circuit structure, and extending in the vertical direction.

6. The semiconductor memory device of claim 1, wherein the first vertical channel transistor and the second vertical channel transistor comprise metal-oxide semiconductor field effect transistors (MOSFETs) of an identical type.

7. The semiconductor memory device of claim 6, further comprising:
a conductive plate arranged between the second vertical channel transistor and the plurality of word line plates; and
a resistor separating the vertical bit line from the conductive plate,
wherein the vertical bit line penetrates the conductive plate.

8. The semiconductor memory device of claim 1, wherein each of the plurality of word line plates has a flat plate shape extending in each of the first horizontal direction and a second horizontal direction different from the first horizontal direction.

9. The semiconductor memory device of claim 1, wherein the plurality of word line plates, the vertical bit line, and the selector arranged between the plurality of word line plates and the vertical bit line constitute a memory cell string including a plurality of memory cells.

10. The semiconductor memory device of claim 9,
wherein the selector comprises a selection substance layer having ovonic threshold switching (OTS) characteristics, a first selection electrode layer between the selection substance layer and the vertical bit line, and a second selection electrode layer between the word line plate and the selection substance layer.

11. A semiconductor memory device comprising:
at least one first source line extending in a first horizontal direction;
at least one second source line extending in the first horizontal direction parallel with the at least one first source line;
a plurality of word line plates arranged apart from each other in a vertical direction and extending in each of the first horizontal direction and a second horizontal direction orthogonal to the first horizontal direction, between the at least one first source line and the at least one second source line;
a plurality of vertical bit lines, extending in the vertical direction, and each extending through the plurality of word line plates, and being spaced apart from each other in each of the first horizontal direction and the second horizontal direction;
a plurality of selectors respectively separating the plurality of word line plates from the plurality of vertical bit lines;
a plurality of first vertical channel transistors respectively arranged between the plurality of vertical bit lines and the at least one first source line; and
a plurality of second vertical channel transistors respectively arranged between the plurality of vertical bit lines and the at least one second source line,
wherein the plurality of word line plates, one vertical bit line among the plurality of vertical bit lines, and the selectors separating the plurality of word line plates and the one vertical bit line among the plurality of selectors constitute a memory cell string including a plurality of memory cells.

12. The semiconductor memory device of claim 11, further comprising:
a plurality of first gate lines respectively constituting the plurality of first vertical channel transistors, and extending in parallel with each other in the second horizontal direction;
a plurality of second gate lines respectively constituting the plurality of second vertical channel transistors, and extending in parallel with each other in the second horizontal direction; and
a plurality of first contact vias configured to electrically connect the plurality of first gate lines to the plurality of second gate lines, and extending in the vertical direction.

13. The semiconductor memory device of claim 11, wherein one vertical channel transistor among the first vertical channel transistor and the second vertical channel transistor comprises a metal-oxide semiconductor field effect transistor (MOSFET) of a p-type, and the other comprises a MOSFET of an n-type.

14. The semiconductor memory device of claim 13,
wherein the at least one second source line has a flat plate shape extending in each of the first horizontal direction and the second horizontal direction, and
wherein the at least one first source line is a plurality of first source lines extending in parallel with each other in the first horizontal direction.

15. The semiconductor memory device of claim 13,
wherein the at least one first source line has one flat plate shape extending in each of the first horizontal direction and the second horizontal direction, and
wherein the at least one second source line is a plurality of second source lines extending in parallel with each other in the first horizontal direction.

16. The semiconductor memory device of claim 11, wherein both the first vertical channel transistor and the second vertical channel transistor comprise metal-oxide semiconductor field effect transistors (MOSFETs) of an n-type or a p-type.

17. The semiconductor memory device of claim 16, further comprising a plurality of second contact vias electrically connecting the plurality of first source lines to the plurality of second source lines corresponding to each other and extending in the vertical direction,
wherein the at least one first source line is a plurality of first source lines extending in parallel with each other in the first horizontal direction, and
wherein the at least one second source line is a plurality of second source lines extending in parallel with each other in the first horizontal direction.

18. A semiconductor memory device comprising:
a plurality of first source lines extending in parallel with each other in a first horizontal direction;
a plurality of second source lines extending in parallel with each other in the first horizontal direction;
a plurality of word line plates spaced apart from each other in a vertical direction and extending in each of the first horizontal direction and a second horizontal direction orthogonal to the first horizontal direction, between the plurality of first source lines and the plurality of second source lines;
a plurality of vertical bit lines respectively, extending in the vertical direction, and extending through the plurality of word line plates, and being spaced apart from each other in each of the first horizontal direction and the second horizontal direction;
a plurality of selectors respectively arranged between the plurality of vertical bit lines and the plurality of word line plates, the plurality of selectors each including a selection substance layer having ovonic threshold switching (OTS) characteristics, a first selection electrode layer arranged between the selection substance layer and each of the plurality of vertical bit lines, and a second selection electrode layer arranged between each of the plurality of word line plates and the selection substance layer;
a plurality of first semiconductor structures each including a first source region, a first channel region, and a first drain region, the plurality of first semiconductor structures being sequentially arranged from the plurality of first source lines toward the plurality of vertical bit lines;
a plurality of first gate lines extending in parallel with each other in the second horizontal direction, and surrounding the first channel regions of the plurality of first semiconductor structures;
a plurality of first gate insulating layers arranged between the plurality of first gate lines and the first channel regions of the plurality of first semiconductor structures;
a plurality of second semiconductor structures each including a second source region, a second channel region, and a second drain region, the plurality of second semiconductor structures being sequentially arranged from the plurality of second source lines toward the plurality of vertical bit lines;
a plurality of second gate lines extending in parallel with each other in the second horizontal direction, and surrounding the second channel regions of the plurality of second semiconductor structures; and
a plurality of second gate insulating layers arranged between the plurality of second gate lines and the second channel regions of the plurality of second semiconductor structures.

19. The semiconductor memory device of claim 18,
wherein the first source region, the first drain region, and the second channel region comprise a first conductivity type, and
wherein the second source region, the second drain region, and the first channel region comprise a second conductivity type different from the first conductivity type.

20. The semiconductor memory device of claim 18,
wherein the first source region, the first drain region, the second source region, and the second drain region comprise a first conductivity type, and
wherein the first channel region and the second channel region comprise a second conductivity type different from the first conductivity type.
